(19) United States
(12) Patent Application Publication
(10) Pub. No.: US 2009/0305062 A1
(43) Pub. Date: Dec. 10, 2009

(54) METHOD FOR FABRICATING MULTILAYERED ENCAPSULATION THIN FILM HAVING OPTICAL FUNCTIONALITY AND MUTILAYERED ENCAPSULATION THIN FILM FABRICATED BY THE SAME

(75) Inventors: Yun Hyuk CHOI, Seoul (KR); Jong Jin PARK, Yongin-si (KR); Young Gu LEE, Suwon-si (KR); Kwang Hee LEE, Suwon-si (KR); Xavier BULLIARD, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/272,381

(22) Filed: Nov. 17, 2008

(30) Foreign Application Priority Data
Jun. 5, 2008 (KR) 10-2008-0053196

(51) Int. Cl. C23C 14/34; B32B 9/04

(52) U.S. Cl. 428/447; 204/192.15

(57) ABSTRACT

A method for fabrication of a multilayered encapsulation thin film having optical functionality and a multilayered encapsulation thin film fabricated thereof includes a reactive or a non-reactive PVD process using a physical vapor deposition device containing multiple targets in a vacuum chamber is conducted or the above processes are alternately conducted such that the multilayered encapsulation thin film consisting of multiple layers with different densities and refractive indexes may be easily fabricated. In addition, the multilayered encapsulation thin film fabricated by the same has superior ability for inhibiting moisture and/or oxygen penetration sufficient to be used as an encapsulation material, controls a refractive index distribution for multiple layers in fabrication of a multilayered thin film so as to function as an anti-reflection film, and improves light output of a device.

### CROSS-REFERENCE TO RELATED APPLICATION

This application claims priority to Korean Patent Application No. 10-2008-0053196, filed on Jun. 5, 2008, and all the benefits accruing there from under 35 U.S.C. §119, the contents of which in its entirety are herein incorporated by reference.

### BACKGROUND

1. Field

This disclosure relates to a method for fabricating a multilayered encapsulation thin film having optical functionality and a multilayered encapsulation thin film fabricated by the same. More particularly, disclosed are a method for fabricating a multilayered encapsulation thin film having optical functionality which includes conducting a reactive or a non-reactive physical vapor deposition (“PVD”) process using a physical vapor deposition device containing multiple targets in a vacuum chamber or conducting the above processes alternately so as to easily fabricate the multilayered encapsulation thin film consisting of individual layers with different densities and refraction indexes, and a multilayered encapsulation thin film fabricated by the same.

2. Description of the Related Art

It is known that an organic material generally contained in an electronic display device such as an organic light emitting device (“OLED”) or a liquid crystal display (“LCD”) is readily damaged by oxygen or moisture, which exists in the atmosphere. If the organic material is exposed to oxygen or moisture, this may cause power reduction and/or early deterioration of performance of the device. There have been developed a method for extending service life of a device using metal and glass materials so as to protect the device, however, a metal substance generally has limited transparency while glass exhibits insufficient flexibility. Therefore, there is a need for an improved transparent barrier film or encapsulation thin film having favorable flexibility which is useful for encapsulating electronic devices such as, for example, thin, light and flexible OLEDs.

In recent years, there has been developed an encapsulation thin film for a display device and/or a moisture barrier layer for a flexible substrate that includes multiple layers laminated by an inorganic deposition method and has a construction of at least two inorganic layers and an organic substance or a polymer layer interposed therebetween so as to improve crack resistance and/or flexibility. However, the above technique may use an expensive deposition system for inorganic deposition, adopts a batch type processing method incurring high production cost and, if a polymer layer is interposed between inorganic layers, may demand a relatively complex process.

A chemical vapor deposition (“CVD”) process has also been developed. This process includes feeding a precursor material such as silane SiH₄ or tetraethoxysilane (“TEOS”) to a substrate and allowing a chemical reaction including, for example, pyrolysis, photolysis, redox reaction, substitution, and the like, on a surface of the substrate. The CVD process may have superior uniformity of a thin film, easy application to large area processing and simple formation of microfine patterns, thereby now being used in a wide range of semiconductor applications. However, the CVD process is performed under high temperatures and uses a harmful chemical as the precursor and, therefore, is not suitable to directly form a thin film over an organic electronic device.

Accordingly, development of an easy and simple method for fabrication of a thin film without performance reduction in an organic electronic device is still needed.

### SUMMARY

Disclosed herein is a method for fabrication of a multilayered encapsulation thin film having optical functionality which is effectively used to easily fabricate the multilayered encapsulation thin film consisting of multiple layers with different densities and refractive indexes.

Disclosed herein is also a multilayered encapsulation thin film with improved optical functionality fabricated by the method described above, which has superior ability for inhibiting moisture and/or oxygen penetration sufficient to encapsulate an electronic device, controls a refractive index distribution for multiple layers in fabrication of a multilayered thin film so as to function as an anti-reflection film, and improves light output of a device.

Disclosed herein is an electronic device having the multilayered encapsulation thin film with improved optical functionality described above, which exhibits superior protection against moisture and/or oxygen penetration.

In one embodiment, there is provided a method for fabrication of a multilayered encapsulation thin film with optical functionality using a PVD system containing multiple targets in a vacuum chamber, including:

using some of the targets contained in the vacuum chamber and forming a first thin film on a substrate by a reactive or non-reactive PVD process; and

using the remaining targets and forming a second thin film over the first thin film by the reactive or non-reactive PVD process.

In another embodiment, there is provided a multilayered encapsulation thin film with optical functionality fabricated by the method described above, which is effectively used in various applications including, for example, a direct encapsulation thin film for electronic devices, a barrier layer, a getter, an anti-corrosive encapsulation material, a heat resistant coating, an anti-reflection film, an infrared filter, a light output enhancing layer, etc.

### BRIEF DESCRIPTION OF THE DRAWINGS

Exemplary embodiments will be more clearly understood from the following detailed description taken in conjunction with the accompanying drawings. FIGS. 1-8 represent non-limiting, exemplary embodiments as described herein.

FIG. 1 is a schematic cross-sectional view illustrating a multilayered encapsulation thin film according to one embodiment in the disclosure;

FIG. 2 is a schematic cross-sectional view illustrating a multilayered encapsulation thin film according to another embodiment in the disclosure;

FIG. 3 is a schematic cross-sectional view illustrating a multilayered encapsulation thin film according to another embodiment in the disclosure;

FIG. 4 is a schematic cross-sectional view illustrating a multilayered encapsulation thin film according to another embodiment in the disclosure;

FIG. 5 is a cross-sectional FE-SEM photograph showing a multilayered encapsulation thin film prepared in Example 1;

FIG. 6 is a cross-sectional FE-SEM photograph showing a single layer thin film prepared in Comparative Example 1;

FIG. 7 is a cross-sectional FE-SEM photograph showing a single layer thin film prepared in Comparative Example 2;

FIG. 8A is a graph illustrating a variation in thickness of a single layer thin film prepared in Comparative Example 3, with respect to passage of sputtering time;

FIG. 8B is a graph illustrating a variation in thickness of a single layer thin film prepared in Comparative Example 4, with respect to passage of sputtering time;

FIG. 9 is a graph illustrating a film density of each of the single layer thin films prepared in Comparative Examples 3 and 4, respectively, with respect to thin film thickness;

FIG. 10 is a graph illustrating a water vapor transmission rate of each of the single layer thin films prepared in Comparative Examples 3 and 4, respectively, with respect to thin film thickness;

FIG. 11 is a schematic cross-sectional view illustrating an OLED laminated with any one of the thin films prepared in Examples 1 to 10 and Comparative Example 6; and

FIG. 12 is a graph illustrating a variation in color coordinates with respect to OLEDs laminated with thin films prepared in Examples 1 to 10 and Comparative Example 6.

### DETAILED DESCRIPTION

The disclosed embodiments will now be described in greater detail with reference to the accompanying drawings.

In one exemplary embodiment, there is provided a method for fabrication of a multilayered encapsulation thin film with optical functionality that uses a PVD system containing multiple targets in a vacuum chamber and includes:

using some of the targets contained in the vacuum chamber and forming a first thin film on a substrate by a reactive or non-reactive PVD process; and

using the remaining targets and forming a second thin film over the first thin film by the reactive or non-reactive PVD process.

Using the PVD system containing multiple targets in a vacuum chamber, the above method may have: embodying two modes of PVD processes in the same system to simplify the process; performing the deposition at room temperature, unlike a CVD process; and not using toxic chemical sources.

In another exemplary embodiment, the method further includes an operation of coating an Si containing organic-inorganic hybrid polymer to a substrate and thermally curing the coated substrate to form an anchoring layer. With such configuration, the anchoring layer serves to buffer stress between the substrate and the first thin film to inhibit crack generation in the first thin film, and improves adhesion between the substrate and the first thin film to enhance moisture and oxygen penetration resistance.

The substrate includes a substrate for electronic device and other substrates commonly available for packaging. More particularly, the substrate may include polyoxymethylene, polyvinylnaphthalene, polyetherketone, fluoro polymer, poly(α-methylstyrene), polysulfone, polyphenyleneoxide, polyetherimide, polyethersulfone, polyamideimide, polyimide, polyphthalamide, polycarbonate, polyarylate, polyethylene naphthalate, polyethylene terephthalate and so on, but is not particularly limited thereto.

The anchoring layer described in the above embodiment is a layer between an inorganic film and an organic substrate, which may contain organic and inorganic materials in combination in order to improve adhesiveness of an interfacial side therebetween. More particularly, in order to improve adhesiveness and/or flexibility of the interfacial side, the anchoring layer may include at least one of compounds represented by the following formulae 1 to 3:

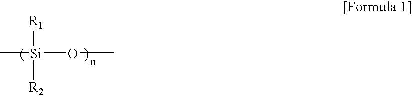

wherein, R₁ and R₂ are each independently a hydrogen atom, or C₁-C₃ alkyl, C₃-C₁₀ cycloalkyl or C₆-C₁₅ aryl group, and n is an integer in a range of about 2,000 to about 200,000;

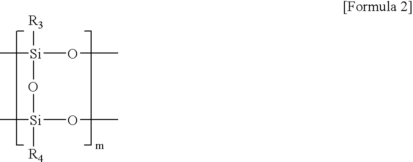

wherein, R₃ and R₄ are each independently a hydrogen atom, or C₁-C₃ alkyl, C₃-C₁₀ cycloalkyl or C₆-C₁₅ aryl group, and m is an integer in a range of about 2,000 to about 200,000; and

—(SiR₅R₆—NR₇)ₒ— [Formula 3]

wherein, R₅R₆, and R₇ are identical or different and at least one thereof is a hydrogen atom, or C₁-C₅ alkyl, C₂-C₅ alkenyl, C₂-C₅ alkynyl, C₂-C₅ alkoxy or C₃-C₈ aromatic group, and o is an integer in a range of about 500 to about 1,000,000.

The above method may further include an operation of forming an organic protective layer over the second thin film by vapor deposition polymerization (“VDP”) after operation (b).

VDP includes feeding at least two source gases into the vacuum chamber and maintaining the gases at room temperature in order to proceed with deposition. In an exemplary embodiment, an isocyanate monomer and a diamine precursor are fed to the chamber under a vacuum pressure of 0.49 Pa to polymerize and deposit a polyurea layer on the second thin film. In this case, polyurea increases at a growth rate of 0.1 μm/min at room temperature.

The organic protective layer may include an acrylic resin such as polyurea, polystyrene, polycarbonate, Paramethoxymethamphetamine (“PMMA”), etc., but is not particularly limited thereto.

Another exemplary embodiment is directed to a method for fabricating a multilayered encapsulation thin film that includes: using some of the targets contained in the vacuum chamber and forming a first thin film on a substrate by a reactive PVD process; and using the remaining targets and forming a second thin film over the first thin film by a non-reactive PVD process.

In another exemplary embodiment is directed to a method for fabricating a multilayered encapsulation thin film that includes: using some of the targets contained in the vacuum chamber and forming a first thin film on a substrate by a non-reactive PVD process; and using the remaining the targets and forming a second thin film over the first thin film by a reactive PVD process.

In another exemplary embodiment, the above method may include the reactive PVD process and the non-reactive process, both being repeated at least one time to laminate alternately the first thin film and the second thin film on the substrate.

Herein, the reactive PVD process includes: applying an electric field around the targets; feeding an inert gas into the chamber; and feeding at least one reactive gas selected from oxygen and nitrogen into the chamber so that a material separated from the targets by the inert gas is mixed with the reactive gas to form a thin film on the substrate.

As disclosed above, in fabrication of the thin film by the reactive PVD process, the reactive gas such as oxygen or nitrogen accelerates the deposition to produce a loose configuration of film. As a result, this film has a low density and, thus, a low refractive index.

On the other hand, the non-reactive PVD process includes: applying an electric field around the targets; feeding inert gas into the chamber; and using a material separated from the targets by the inert gas to form a thin film on the substrate.

In fabrication of the thin film by the non-reactive PVD process, the deposition rate is lower than that in the fabrication of thin film by the reactive PVD process, thereby producing the film with a dense configuration. Accordingly, this film has a relatively high density, thus, a high refractive index.

In one exemplary embodiment, the reactive PVD process is performed using aluminum Al as a target, applying an electric field around the target and feeding Ar as an inert gas and oxygen gas as a reactive gas into a vacuum chamber, Al separated from the target by Ar is mixed with oxygen to form a first thin film having a composition of Al₂O₃ on a substrate. As described above, since the reactive gas accelerates the deposition rate, the first thin film has a low density and a low refractive index.

Following this, when the non-reactive PVD process is performed by using Al₂O₃ as another target, applying an electric field around the target and feeding Ar as the inert gas into the chamber, Al₂O₃ separated from the target by Ar forms a second thin film having a composition of Al₂O₃ over the first thin film. As described above, due to the low deposition rate, the second thin film has a high density and a high refractive index.

Accordingly, the first thin film and the second thin film fabricated by different types of PVD process may have densities and refractive indexes different from each other although they have the same composition of constitutional ingredients.

In another exemplary embodiment, after forming a first thin film with a composition of Al₂O₃ by the reactive or non-reactive PVD process, a second thin film with a composition of TiO₂ may be formed over the first thin film by the reactive or non-reactive PVD process. In this regard, the composition, density and/or refractive index of the first thin film may be different from those of the second thin film.

According to the disclosed method, since the thin film obtained by the reactive PVD process has a low density, the film shows somewhat deteriorated ability for inhibiting penetration of moisture and/or oxygen if used as a protective film. However, sputtering particles having a relatively low energy deposited on the thin film may considerably reduce damage to a substrate or device.

On the contrary, although the thin film formed by the non-reactive PVD process, which includes sputtering particles having a relatively high energy deposited thereon, may cause damage to a substrate or device, the film may have a high density and, thus, superior ability to inhibit oxygen or moisture penetration if used as a protective film.

The target material may include at least one selected from a group consisting of: a metal element such as Al, Si, B, Ti, Sn, Zn, In, Zr and Ge; a metal oxide such as Al₂O₃, SiO₂, B₂O₅, TiO₂, SnO₂, ZnO, In₂O₃, ZrO₂, GeO₂ and AlSiOₓ; a metal nitride such as AlN, Si₃N₄, TiN, ZrN and BN; a metallic acid nitride such as AlON, SiON and AlSiON; InSnO, SiZnO, InZnO and InGaZnO; and any mixtures thereof, but is not particularly limited thereto.

For the reactive PVD process, the target is mostly a metal substance such as Al, Si, B, Ti, Sn, Zn, In, Zr or Ge, which is mixed with the reactive gas, that is, oxygen or nitrogen to form a thin film. For the non-reactive PVD process, a constitutional ingredient of the thin film is mostly used as the target.

The thin film may include at least one inorganic material selected from a group consisting of: a metal oxide such as Al₂O₃, SiO₂, B₂O₅, TiO₂, SnO₂, ZnO, In₂O₃, ZrO₂, GeO₂ and AlSiOₓ, wherein “x” is an integer between 1-4; a metal nitride such as AlN, Si₃N₄, TiN, ZrN and BN; a metallic acid nitride such as AlON, SiON and AlSiON; InSnO, SiZnO, InZnO and InGaZnO; and any mixtures thereof, but is not particularly limited thereto.

The PVD process used in the disclosed method may include sputtering, pulsed laser deposition (“PLD”), ion beam deposition (“IBD”), ion beam assisted deposition (“IBAD”), etc., but is not particularly limited thereto.

The PVD process may also include co-deposition using multiple targets, for example, co-sputtering, co-PLD, co-IBD, co-IBAD, etc., but is not particularly limited thereto.

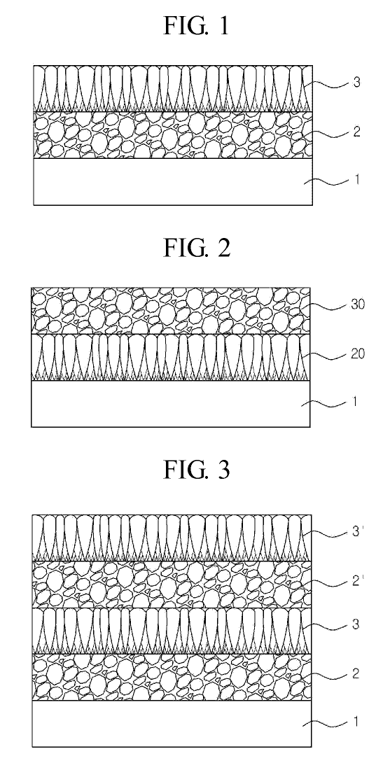

In another exemplary embodiment, there is provided a multilayered encapsulation thin film with optical functionality fabricated by the method described above. FIGS. 1 to 4 are schematic cross-sectional views illustrating the multilayered encapsulation thin films with optical functionality fabricated by the disclosed methods. Referring to FIG. 1, a multilayered encapsulation thin film with optical functionality fabricated according to an exemplary embodiment of the disclosed method includes a first thin film 2 formed on a substrate 1 by a reactive PVD process and a second thin film 3 formed over the first thin film 2 by a non-reactive PVD process.

In another exemplary embodiment, as shown in FIG. 2, a multilayered encapsulation thin film with optical functionality includes a first thin film 20 formed on a substrate 1 by a non-reactive PVD process and a second thin film 30 formed over the first thin film 20 by a reactive PVD process.

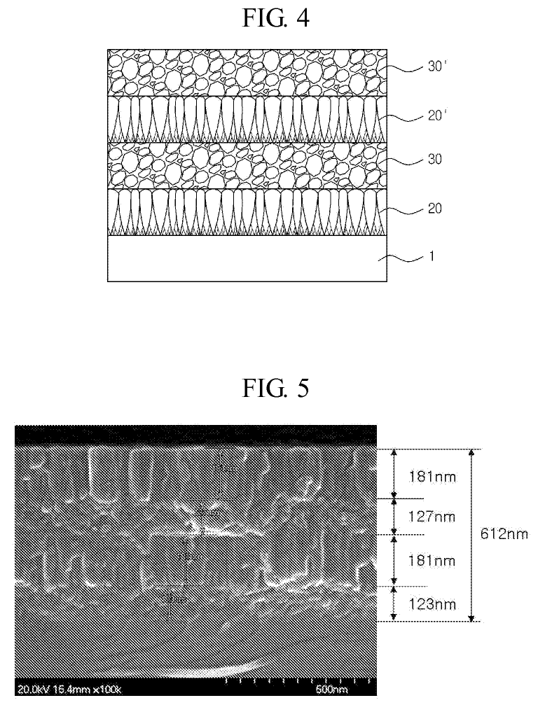

In another exemplary embodiment, a multilayered encapsulation thin film with optical functionality may include at least one pair or two or more pairs of first and second thin films. Referring to FIGS. 3 and 4, the multilayered encapsulation films with optical functionality may have two pairs of the first thin films (2 and 2′, 20 and 20′) and second thin films (3 and 3′, 30 and 30′), respectively.

The thin film formed by the reactive PVD process may have a low density and a low refractive index while the thin film formed by the non-reactive PVD process may have a high density and a high refractive index.

According to a further exemplary embodiment, the multilayered encapsulation thin film with optical functionality may further include an anchoring layer, which includes at least one selected from compounds represented by the following formulae 1 to 3, between the substrate and the first thin film, thereby increasing adhesion between the thin film and the substrate:

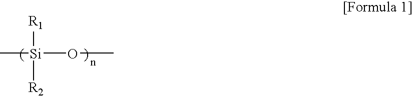

wherein, R₁ and R₂ are each independently a hydrogen atom, or C₁-C₃ alkyl, C₃-C₁₀ cycloalkyl or C₆-C₁₅ aryl, and n is an integer in a range of about 2,000 to about 200,000;

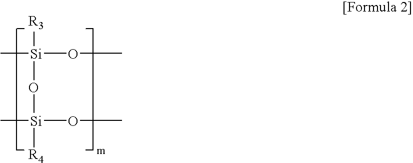

wherein, R₃ and R₄ are each independently a hydrogen atom, or C₁-C₃ alkyl, C₃-C₁₀ cycloalkyl or C₆-C₁₅ aryl, and m is an integer in a range of about 2,000 to about 200,000; and

—(SiR₅R₆—NR₇)ₒ— [Formula 3]

wherein, R₅, R₆, and R₇ are identical or different and at least one thereof is a hydrogen atom, or C₁-C₅ alkyl, C₂-C₅ alkenyl, C₂-C₅ alkynyl, C₂-C₅ alkoxy or C₃-C₈ aromatic group, and o is an integer in a range of about 500 to about 1,000,000.

In another exemplary embodiment, the multilayered encapsulation thin film with optical functionality may also include an organic protective layer over the second thin film to endow scratch resistance to the thin film. The organic protective layer consisting of hydrophobic materials may greatly improve a water barrier property of the film.

The first thin film may have a density and a refractive index different from those of the second thin film depending on whether the reactive or non-reactive PVD process is used, although both of the thin films have the same composition of constitutional ingredients. Likewise, depending on the target material, the first thin film may have a composition of constitutional ingredients, a density and a refractive index different from those of the second thin film.

The disclosed multilayered encapsulation thin film has superior ability to inhibit oxygen and/or moisture penetration and, in addition, may be used as an encapsulation material such as a direct encapsulation thin film material for electronic devices, a barrier layer, a getter, an anti-corrosive encapsulation material and the like.

For a laminate including only thin films with high densities by the non-reactive PVD process, the laminate may show improved moisture barrier properties but necessarily encounters a problem of causing direct impact to a substrate and/or a device by high energy sputtering particles in the thin film. For this reason, in order to protect an organic device and/or a substrate located under a multilayered encapsulation thin film while improving overall moisture barrier properties, a thin film containing low energy sputtering particles is deposited on the device and/or the substrate by the reactive PVD process, followed by deposition of high energy sputtering particles over the thin film using the non-reactive PVD process.

The multilayered encapsulation thin film according to the disclosure, which has sequentially ordered refractive indexes of multiple layers, exhibits light output improvement to allow the thin film to be used as a light output enhancing layer and has an anti-reflection property sufficient to allow the thin film to be used as an anti-reflection film or an infrared filter.

Moreover, if the multilayered encapsulation thin film is fabricated by alternately laminating multiple thin films having the same composition, the thin film has no difference in interlayer thermal expansion coefficients thereby being effectively used as a heat resistant coating material.

In yet another aspect of the disclosure, there is provided an electronic device having a multilayered encapsulation thin film with optical functionality. The multilayered encapsulation thin film with optical functionality has high resistance against diffusion of chemical materials as well as superior ability for inhibiting oxygen and/or moisture penetration. Therefore, when the thin film is used to encapsulate a variety of electronic devices, the thin film effectively extends life times of the devices.

Such electronic device may include an organic light emitting device (“OLED”), a display device, a photoelectric device, an integrated circuit, a pressure sensor, a chemical sensor, a bio sensor, a solar sensor, a lighting device and so on, but exemplary embodiments are not particularly limited thereto.

Hereinafter, the disclosed embodiments will be explained in more detail with reference to the following examples. However, these examples are given for the purpose of illustration and are not intended to limit the disclosure.

### EXAMPLES

### Production of Encapsulation Thin Film

### Example 1

### Fabrication of Multilayered Encapsulation Thin Film

Using a physical vapor deposition system Sputter Infovion No. 3 available from Infovion Co., Ltd. (2 gun co-sputtering, 6 inch substrate), a first thin film is formed on a polyethylene terephthalate (“PET”) substrate with a thickness of 100 μm. Some targets contained in a vacuum chamber of the system are used to form the first thin film by a reactive RF magnetron sputtering process. The used targets are Al (Ø6″, 99.99% purity). After Ar (98 sccm) and O₂ (2 sccm) are fed to the vacuum chamber to separate Al from the targets, an electric field is applied to the Al targets, to proceed with a reaction of the separated Al with O₂. As a result, an Al₂O₃ thin film (first thin film) is formed on the substrate. The sputtering is continued for 1,200 seconds.

Next, the remaining targets are used to form a second thin film by a non-reactive RF magnetron sputtering process. The used targets are Al₂O₃ (Ø6″, 99.99% purity). First, after applying an electric field to the Al₂O₃ targets, Ar (100 sccm) is fed to the vacuum chamber to separate Al₂O₃ from the targets and form an Al₂O₃ thin film (second thin film) from the separated Al₂O₃ on the substrate. The sputtering is continued for 96 minutes.

### Example 2

### Fabrication of Multilayered Encapsulation Thin Film

A multilayered encapsulation thin film is fabricated according to the same procedure as in Example 1, except that the process including formation of the first thin film followed by formation of the second film is repeated twice. FIG. 5 shows a cross-sectional field electron scanning electron microscope (“FE-SEM”) photograph of the resultant multilayered encapsulation thin film. Referring to FIG. 5, it may be seen that this thin film included four layers including a first thin film (123 nm), a second thin film (181 nm), another first thin film (127 nm) and another second thin film (181 nm) laminated on a substrate in this order. The multilayered encapsulation thin film has a thickness of 612 nm.

### Example 3

### Fabrication of Multilayered Encapsulation Thin Film

A multilayered encapsulation thin film is fabricated according to the same procedure as in Example 1, except that the first thin film is firstly formed by a non-reactive RF magnetron sputtering process, followed by formation of the second thin film using a reactive RF magnetron sputtering process.

### Example 4

### Fabrication of Multilayered Encapsulation Thin Film

Using a physical vapor deposition system Sputter Infovion No. 3 available from Infovion Co., Ltd. (2 gun co-sputtering, 6 inch substrate), a first thin film is formed on a PET substrate with a thickness of 100 μm. Some targets contained in a vacuum chamber of the system are used to form the first thin film by a non-reactive RF magnetron sputtering process. The used targets are Al₂O₃ (Ø6″, 99.99% purity). First, after applying an electric field to the Al₂O₃ targets, Ar (100 sccm) is fed to the vacuum chamber to separate Al₂O₃ from the targets and form an Al₂O₃ thin film (first thin film) from the separated Al₂O₃ on the substrate. The sputtering is continued for 32 minutes.

Next, the remaining targets are used to form a second thin film on the first thin film by a non-reactive RF magnetron sputtering process. The used targets are TiO₂ (Ø6″, 99.99% purity). First, after applying an electric field to the TiO₂ targets, Ar (100 sccm) is fed to the vacuum chamber to separate TiO₂ from the targets and form a TiO₂ thin film (second thin film) from the separated TiO₂ on the substrate. The sputtering is continued for 15 minutes.

### Example 5

### Fabrication of Multilayered Encapsulation Thin Film

A multilayered encapsulation thin film is fabricated according to the same procedure as in Example 4, except that the process including formation of the first thin film followed by formation of the second film is repeated twice.

### Example 6

### Fabrication of Multilayered Encapsulation Thin Film

A multilayered encapsulation thin film is fabricated according to the same procedure as in Example 4, except that the process including formation of the first thin film followed by formation of the second film is repeated three times.

### Example 7

### Fabrication of Multilayered Encapsulation Thin Film

A multilayered encapsulation thin film is fabricated according to the same procedure as in Example 1, except that an organic protective layer is formed over the second thin film prepared in Example 1 by a vapor deposition polymerization process. That is, the multilayered encapsulation thin film is fabricated by the same procedure as in Example 1 except that the vapor deposition polymerization process is conducted using a methylenedi(p-phenylene) diisocyanate monomer represented by Formula 4 and a 4,4′-methylenedianiline precursor represented by Formula 5 as sources to form a polyurea layer with an overall thickness of 1 μm at room temperature under conditions of a deposition rate of 0.1 μm/min and a deposition pressure of 0.49 Pa.

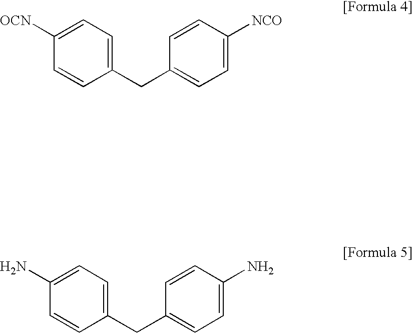

### Example 8

### Fabrication of Multilayered Encapsulation Thin Film

A multilayered encapsulation thin film is fabricated according to the same procedure as in Example 2, except that an organic protective layer is formed over the second thin film prepared in Example 2 by a vapor deposition polymerization process. That is, the multilayered encapsulation thin film is fabricated by the same procedure as in Example 2 except that the vapor deposition polymerization process is conducted using a methylenedi(p-phenylene) diisocyanate monomer represented by Formula 4 and a 4,4′-methylenedianiline precursor represented by Formula 5 as sources to form a polyurea layer with an overall thickness of 1 μm at room temperature under conditions of a deposition rate of 0.1 μm/min and a deposition pressure of 0.49 Pa.

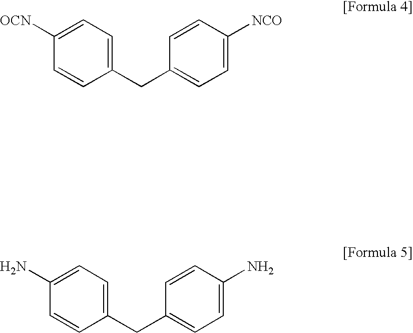

### Example 9

### Fabrication of Multilayered Encapsulation Thin Film

A multilayered encapsulation thin film is fabricated according to the same procedure as in Example 7, except that an anchoring layer is formed before forming a first thin film on the substrate. That is, dissolving 1.16 g of an organic-inorganic hybrid siloxane polymer represented by Formula 6 in 3.87 g of propyleneglycol monomethylether acetate, resulted in a coating solution with a solid content of 23% by weight. The coating solution is applied to a PET substrate with a thickness of 100 μm via spin coating. Subsequently, the coated PET substrate is thermally cured on a hot plate at 50° C. for 5 minutes, followed by curing in a vacuum oven at 60° C. for 2 hours, thereby producing the anchoring layer.

Following this, the multilayered encapsulation thin film is fabricated by the same procedure as in Example 7 wherein a first thin film, a second thin film and an organic protective layer are formed in this order.

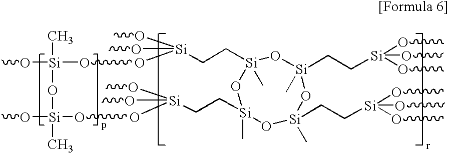

wherein p and r are each independently an integer in a range of about 50 to about 500,000.

### Example 10

### Fabrication of Multilayered Encapsulation Thin Film

A multilayered encapsulation thin film is fabricated according to the same procedure as in Example 8, except that an anchoring layer is formed before forming a first thin film on the substrate. That is, dissolving 1.16 g of an organic-inorganic hybrid siloxane polymer represented by Formula 6 in 3.87 g of propyleneglycol monomethylether acetate, resulted in a coating solution with a solid content of 23% by weight. The coating solution is applied to a PET substrate with a thickness of 100 μm via spin coating. Subsequently, the coated PET substrate is thermally cured on a hot plate at 50° C. for 5 minutes, followed by curing in a vacuum oven at 60° C. for 2 hours, thereby resulting in the anchoring layer.

Following this, the multilayered encapsulation thin film is fabricated by the same procedure as in Example 8 wherein a first thin film, a second thin film, another first thin film, another second thin film and an organic protective layer are formed in this order.

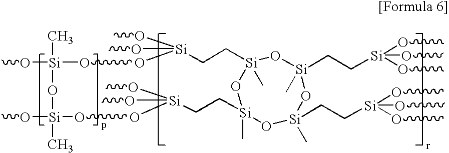

wherein p and r are each independently an integer in a range of about 50 to about 500,000.

### Comparative Example 1

### Fabrication of Single Layer Thin Film Via Non-Reactive RF Magnetron Sputtering Process

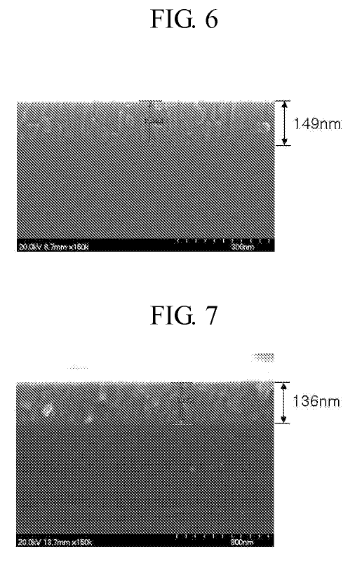

Using a physical vapor deposition system Sputter Infovion No. 3 available from Infovion Co., Ltd. (2 gun co-sputtering, 6 inch substrate), a single layer thin film is formed on a PET substrate with a thickness of 100 μm. Some targets contained in a vacuum chamber of the system are used to form the thin film by a non-reactive RF magnetron sputtering process. The used targets are Al₂O₃ (Ø6″, 99.99% purity). First, after applying an electric field to the Al₂O₃ targets, Ar (100 sccm) is fed to the vacuum chamber to separate Al₂O₃ from the targets and form an Al₂O₃ thin film from the separated Al₂O₃ on the substrate. The sputtering is continued for 96 minutes. FIG. 6 shows a cross-sectional FE-SEM photograph of the resultant single layer thin film.

### Comparative Example 2

### Fabrication of Single Layer Thin Film Via Reactive RF Magnetron Sputtering Process

Using a physical vapor deposition system Sputter Infovion No. 3 available from Infovion Co., Ltd. (2 gun co-sputtering, 6 inch substrate), a single layer thin film is formed on a PET substrate with a thickness of 100 μm. Some targets contained in a vacuum chamber of the system are used to form the thin film by a reactive RF magnetron sputtering process. The used targets are Al (Ø6″, 99.99% purity). First, after applying an electric field to the Al targets, Ar (98 sccm) and O₂ (2 sccm) are fed to the vacuum chamber to separate Al from the targets and proceed a reaction of the separated Al with O₂. As a result, an Al₂O₃ thin film is formed on the substrate. The sputtering is continued for 1,200 seconds. FIG. 7 shows a cross-sectional FE-SEM photograph of the resultant single layer thin film.

### Comparative Example 3

### Fabrication of Single Layer Thin Film Via Non-Reactive RF Magnetron Sputtering Process

Four (4) single layer thin films are fabricated according the same procedure as in Comparative Example 1, except that the sputtering time is adjusted to 32, 64, 96 and 128 minutes, respectively.

### Comparative Example 4

### Fabrication of Single Layer Thin Film Via Reactive RF Magnetron Sputtering Process

Three (3) single layer thin films are fabricated according the same procedure as in Comparative Example 2, except that the sputtering time is adjusted to 600, 1200 and 1800 seconds, respectively.

### Comparative Example 5

### Fabrication of Single Layer Thin Film Via Non-Reactive RF Magnetron Sputtering Process

Using a physical vapor deposition system Sputter Infovion No. 3 available from Infovion Co., Ltd. (2 gun co-sputtering, 6 inch substrate), a single layer thin film is formed on a PET substrate with a thickness of 100 μm. Some targets contained in a vacuum chamber of the system are used to form the thin film by a non-reactive RF magnetron sputtering process. The used targets are TiO₂ (Ø6″, 99.99% purity). First, after applying an electric field to the TiO₂ targets, Ar (100 sccm) is fed to the vacuum chamber to separate TiO₂ from the targets and form a TiO₂ thin film from the separated TiO₂ on the substrate. The sputtering is continued for 15 minutes.

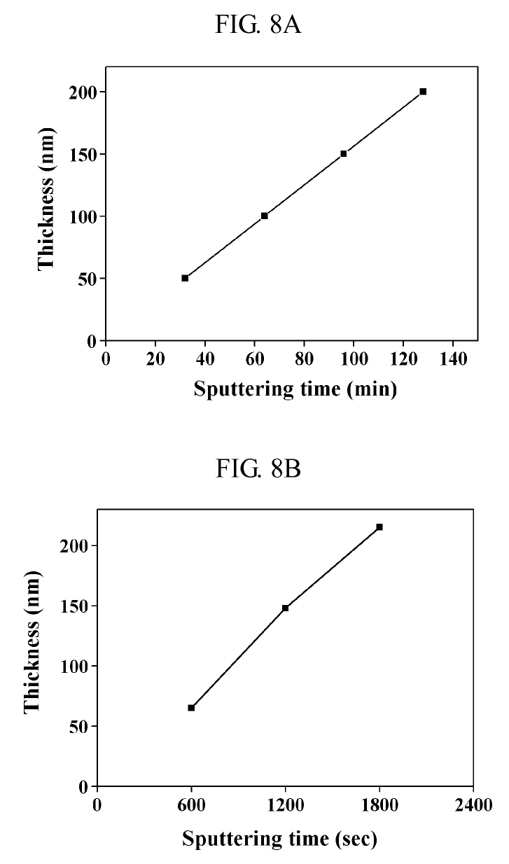

Determination of Deposition Rate Measurement of a variation in thickness of a thin film with respect to sputtering time is conducted for thin films prepared in Comparative Examples 3 and 4. The results are shown in FIGS. 8A and 8B, respectively. Alternatively, a variation in thickness of a thin film with respect to a deposition time is determined by FE-SEM cross-sectional observation and ellipsometry. Referring to FIG. 8A, it is identified that the deposition rate is 0.26 Å/sec in the non-reactive RF magnetron sputtering process while the reactive RF magnetron sputtering process showed a deposition rate of 1.19 Å/sec.

Determination of Thin Film Density

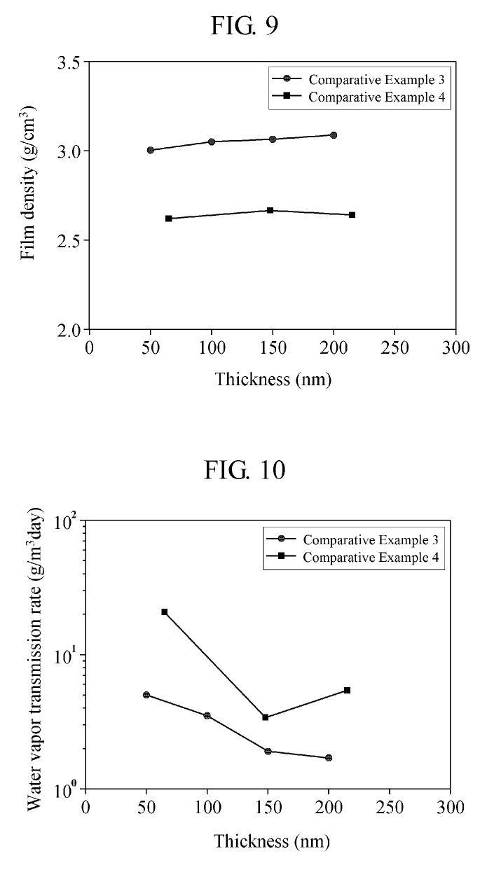

Four thin films with thicknesses of 50 nm, 100 nm, 150 nm and 200 nm prepared in Comparative Example 3 and three thin films with thicknesses of 65 nm, 148 nm and 215 nm prepared in Comparative Example 4 are subjected to determination of thin film density using X-ray reflectivity (“XRP”). The results are shown in FIG. 9. Referring to FIG. 9, it is found that the thin films deposited by the non-reactive RF magnetron sputtering process (Comparative Example 3) had a density of about 3.0 g/cm³, greater than that of the thin films, about 2.6 g/cm³, which are deposited by the reactive RF magnetron sputtering process (Comparative Example 4). This is because the non-reactive RF magnetron sputtering process has a relatively low deposition rate, thus leading to formation of a dense thin film.

Determination of Water Vapor Transmission Rate of Thin Film The encapsulation thin films prepared in Examples 1 to 10 as well as Comparative Examples 3 and 4 are subjected to determination of water vapor transmission rate using a water vapor transmission rate measuring device, AQUATRAN model 1 available from MOCON (USA) at 37.8° C. and 100% R H. The results are shown in the following Table 1. For the thin films prepared in Comparative Examples 3 and 4, the results of measuring the water vapor transmission rate are illustrated in FIG. 10. Referring to FIG. 10, it is found that the thin film with a thickness of 150 nm, which is deposited by the non-reactive RF magnetron sputtering process (Comparative Example 3), had a water vapor transmission rate of about 1.7 g/m²·day lower than that of the thin film, about 3.4 g/m²·day, which is deposited by the reactive RF magnetron sputtering process (Comparative Example 4). The non-reactive RF magnetron sputtering process has a relatively low deposition rate, resulting in a dense thin film. As a result, it is demonstrated that the thin film has relatively improved moisture barrier properties.

As is apparent from Table 1, the multilayered encapsulation films prepared in Examples 1 and 2 according to the disclosed methods have moisture permeabilities of about 0.25 g/m²·day and 0.04 g/m²·day, respectively, which are superior over those of the single layer thin films prepared in Comparative Examples 3 and 4.

With regard to the multilayered encapsulation thin films prepared in Examples 9 and 10, each having an anchoring layer and an organic protective layer, it is identified that these thin films had moisture permeabilities of about 0.12 g/m²·day and 0.01 g/m²·day, which are remarkably improved, compared to a thin film without the anchoring layer.

TABLE 1

| | Water vapor | | | Water vapor |
|---|---|---|---|---|
| | transmission | | Thickness of | transmission |
| | rate | | thin film | rate |
| | (g/m² · day) | | (nm) | (g/m² · day) |
| Example 1 | 0.25 | Comparative | 50 | 5 |
| Example 2 | 0.04 | Example 3 | 100 | 3.5 |
| Example 3 | 0.58 | | | |
| Example 4 | 0.64 | | 150 | 1.9 |
| Example 5 | 0.07 | | 200 | 1.7 |
| Example 6 | 0.04 | Comparative | 65 | 20.7 |
| Example 7 | 0.23 | Example 4 | 148 | 3.4 |
| Example 8 | 0.04 | | | |
| Example 9 | 0.12 | | 215 | 5.4 |
| Example 10 | 0.01 | | | |

Determination of Refractive Index of Thin Film

Refractive index determination is carried out through Ellipsometry for the Al₂O₃ single layer thin films prepared in Comparative Examples 1 and 2 and the TiO₂ single layer thin film prepared in Comparative Example 5. The refractive indexes of the thin films measured at 633 nm are given in Table 2. Table 2 shows that the refractive index of the high density Al₂O₃ single layer thin film deposited by the non-reactive RF magnetron sputtering process (Comparative Example 1) is higher than that of the low density Al₂O₃ single layer thin film deposited by the reactive RF magnetron sputtering process (Comparative Example 1). On the other hand, it is found that the TiO₂ single layer thin film prepared in Comparative Example 5 has a considerably high refractive index of 2.71, compared to Al₂O₃ single layer thin films.

TABLE 2

| | | Refractive |
|---|---|---|
| | | index |
| Sample | Single layer thin film | (at 633 nm) |
| Comparative | Al₂O₃ single layer thin film formed through | 1.65 |
| Ex. 1 | non-reactive RF magnetron sputtering (using | |
| | Al₂O₃ target) | |
| Comparative | Al₂O₃ single layer thin film formed through | 1.57 |
| Ex. 2 | reactive RF magnetron sputtering | |
| | (using Al target) | |
| Comparative | TiO₂ single layer thin film formed through | 2.71 |
| Ex. 5 | non-reactive RF magnetron sputtering | |
| | (using TiO₂ target) | |

Determination of light output properties and color gamut of multilayered encapsulation thin film

### Example A

Application of Multilayered Encapsulation Thin Film to OLED Device Structure

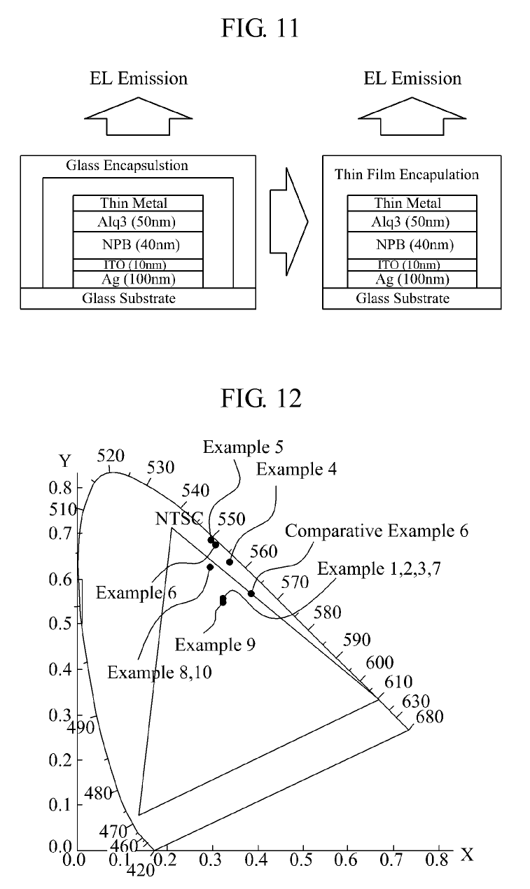

As shown in FIG. 11, an OLED device is fabricated by laminating ITO/NPB (40 nm), Alq₃ (50 nm), LiF (1 nm) and Al (100 nm) in this order. Each of the multilayered encapsulation thin films prepared in Examples 1 to 10 is laminated on the fabricated OLED device. For the completed OLED device with a size of 2 mm×2 mm, a light emitting test is conducted with initial brightness of 1,000 cd/m² at room temperature. The results are shown in Table 3.

Additionally, using a luminance meter PR 650, a variation in color coordinates of the OLED device laminated with the thin film is determined. The results are listed in Table 3 and illustrated in FIG. 12.

### Comparative Example 6

### Application of Glass Encapsulation Layer to OLED Device Structure

An OLED device is subjected to a light emitting test and determination of a variation in color coordinates according to the same procedure as in Example A, except that the OLED device had a glass encapsulation layer laminated thereon instead of the multilayered encapsulation thin film. The results are listed in Table 3 and illustrated in FIG. 12.

TABLE 3

| | |
|---|---|
| | Color |
| Luminescence | coordinate |

| | | efficiency (%) | CIEx | CIEy |
|---|---|---|---|---|
| Example A | Example 1 | 102.3 | 0.320 | 0.564 |
| | Example 2 | 101.6 | 0.320 | 0.564 |
| | Example 3 | 103.8 | 0.320 | 0.564 |
| | Example 4 | 140 | 0.336 | 0.636 |
| | Example 5 | 136 | 0.299 | 0.682 |
| | Example 6 | 139 | 0.305 | 0.675 |
| | Example 7 | 102.1 | 0.320 | 0.564 |
| | Example 8 | 101.1 | 0.298 | 0.623 |
| | Example 9 | 101.8 | 0.320 | 0.563 |
| | Example 10 | 100.9 | 0.298 | 0.623 |

| | | | |
|---|---|---|---|
| Comparative example 6 | 100 | 0.384 | 0.569 |

As is apparent from Table 3, it is understood that Examples 1 to 10 show more improved light output efficiencies than Comparative Example 6. For the multilayered encapsulation thin film including a combination of Al₂O₃ having a low refractive index and TiO₂ having a high refractive index, it is identified that the light output efficiency is improved to a maximum of 40% (Example 4).

A variation in color coordinates represents a color gamut display. In an NTSC coordinate system used as an international standard, a green device corresponds to color coordinate points (0.21, 0.71). Referring to Table 3 and FIG. 11, compared to the glass encapsulation layer (Comparative Example 6) having the color coordinate points (0.384, 0.569), in particular, the thin film prepared in Example 5 among the multilayered encapsulation thin films prepared by the disclosed method (Examples 1 to 10) exhibits the color coordinate points (0.299, 0.682). Therefore, it is demonstrated that the multilayered encapsulation thin film prepared by the disclosed method reproduces an excellent color gamut.

The disclosed embodiments have been described in detail with reference to the foregoing exemplary embodiments. However, those skilled in the art will appreciate that various modifications and variations are possible, without departing from the scope and spirit of the appended claims. Accordingly, such modifications and variations are intended to come within the scope of the claims.

What is claimed is:

1. A method for fabrication of a multilayered encapsulation thin film with optical functionality using a physical vapor deposition (PVD) system containing multiple targets in a vacuum chamber, comprising:
using some of the targets contained in the vacuum chamber and forming a first thin film on a substrate by a reactive or non-reactive PVD process; and
using the remaining targets and forming a second thin film over the first thin film by the reactive or non-reactive PVD process.

2. The method according to claim 1, further comprising: coating an Si containing organic-inorganic hybrid polymer to the substrate; and thermally curing the coated substrate to form an anchoring layer before using some of the targets contained in the vacuum chamber and forming a first thin film on a substrate by a reactive or non-reactive PVD process.

3. The method according to claim 2, wherein the anchoring layer includes at least one selected from compounds represented by Formulae 1 to 3: 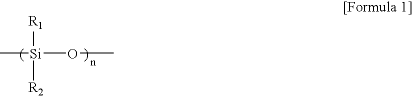
wherein, R₁ and R₂ are each independently a hydrogen atom, or C₁-C₃ alkyl, C₃-C₁₀ cycloalkyl or C₆-C₁₅ aryl group, and n is an integer in a range of about 2,000 to about 200,000; 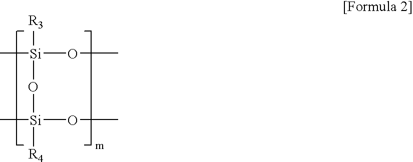
wherein, R₃ and R₄ are each independently a hydrogen atom, or C₁-C₃ alkyl, C₃-C₁₀ cycloalkyl or C₆-C₁₅ aryl group, and m is an integer in a range of about 2,000 to about 200,000; and
—(SiR₅R₆—NR₇)ₒ— [Formula 3]
wherein, R₅, R₆, and R₇ are identical or different and at least one thereof is a hydrogen atom, or C₁-C₅ alkyl, C₂-C₅ alkenyl, C₂-C₅ alkynyl, C₂-C₅ alkoxy or C₃-C₈ aromatic group, and o is an integer in a range of about 500 to about 1,000,000.

4. The method according to claim 1, further comprising; forming an organic protective layer over the second thin film by vapor deposition polymerization (VDP) after using the remaining targets and forming a second thin film over the first thin film by the reactive or non-reactive PVD process.

5. The method according to claim 1, wherein the method comprises, in particular: using some of the targets contained in the vacuum chamber and forming a first thin film on a substrate by a reactive PVD process; and using the remaining targets and forming a second thin film over the first thin film by a non-reactive PVD process.

6. The method according to claim 1, wherein the method comprises, in particular: using some of the targets contained in the vacuum chamber and forming a first thin film on a substrate by a non-reactive PVD process; and using the remaining targets and forming a second thin film over the first thin film by a reactive PVD process.

7. The method according to claim 1, wherein the first thin film has a composition of constitutional ingredients, a density and a refractive index different from those of the second thin film.

8. The method according to claim 1, wherein the reactive PVD process includes: applying an electric field around the targets; feeding an inert gas into the chamber; and feeding at least one reactive gas selected from oxygen and nitrogen into the chamber so that a material separated from the targets by the inert gas is mixed with the reactive gas to form a thin film on the substrate.

9. The method according to claim 1, wherein the non-reactive PVD process includes: applying an electric field around the targets; feeding inert gas into the chamber; and using a material separated from the targets by the inert gas to form a thin film on the substrate.

10. A multilayered encapsulation thin film fabricated by the method according to claim 1.

11. The multilayered encapsulation thin film according to claim 10, wherein the thin film includes a first thin film formed on a substrate by a reactive PVD process and a second thin film formed over the first thin film by a non-reactive PVD process.

12. The multilayered encapsulation thin film according to claim 10, wherein the thin film includes a first thin film formed on a substrate by a non-reactive PVD process and a second thin film formed over the first thin film by a reactive PVD process.

13. The multilayered encapsulation thin film according to claim 11, wherein the thin film includes one pair or two or more pairs of first and second thin films.

14. The multilayered encapsulation thin film according to claim 11, wherein the thin film further includes an anchoring layer comprising at least one selected from compounds represented by Formulae 1 to 3, between the substrate and the first thin film: 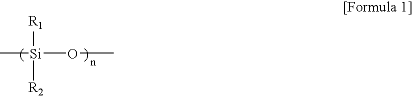
wherein, R₁ and R₂ are each independently a hydrogen atom, or C₁-C₃ alkyl, C₃-C₁₀ cycloalkyl or C₆-C₁₅ aryl group, and n is an integer in a range of about 2,000 to about 200,000; 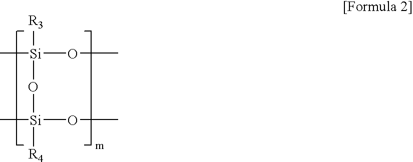
wherein, R₃ and R₄ are each independently a hydrogen atom, or C₁-C₃ alkyl, C₃-C₁₀ cycloalkyl or C₆-C₁₅ aryl group, and m is an integer in a range of about 2,000 to about 200,000; and
—(SiR₅R₆—NR₇)ₒ— [Formula 3]
wherein, R₅, R₆, and R₇ are identical or different and at least one thereof is a hydrogen atom, or C₁-C₅ alkyl, C₂-C₅ alkenyl, C₂-C₅ alkynyl, C₂-C₅ alkoxy or C₃-C₈ aromatic group, and o is an integer in a range of about 500 to about 1,000,000.

15. The multilayered encapsulation thin film according to claim 11, wherein the thin film further includes an organic protective layer formed over the second thin film.

16. The multilayered encapsulation thin film according to claim 11, wherein the first thin film has a density and a refractive index different from those of the second thin film while they have the same composition of constitutional ingredients.

17. The multilayered encapsulation thin film according to claim 11, wherein the first thin film has a composition of constitutional ingredients, a density and a refractive index different from those of the second thin film.

18. The multilayered encapsulation thin film according to claim 10, wherein the thin film is used as a direct encapsulation thin film for electronic devices, a barrier layer, a getter, an anti-corrosive encapsulation material, a heat resistant coating, an anti-reflection film, an infrared filter and/or a light output enhancing layer.

19. An electronic device comprising the multilayered encapsulation thin film with optical functionality according to claim 10.

20. The electronic device according to claim 19, wherein the electronic device includes an organic light emitting device (OLED), a display device, a photoelectric device, an integrated circuit, a pressure sensor, a chemical sensor, a bio sensor, a solar sensor and/or a lighting device.
